(19) United States
(12) Patent Application Publication
(10) Pub. No.: US 2026/0297291 A1
(43) Pub. Date: Oct. 1, 2026

(54) MAGNETIC COMPOSITION, MAGNETIC FILM, STACK, AND CIRCUIT MEMBER

(71) Applicant: Resonac Corporation, Tokyo (JP)

(72) Inventors: Motoki YONEKURA, Tokyo (JP); Kosuke URASHIMA, Tokyo (JP); Motohiro ARIFUKU, Tokyo (JP)

(21) Appl. No.: 19/479,405

(22) PCT Filed: Nov. 20, 2024
(86) PCT No.: PCT/JP2024/041150

§ 371 Date: Oct. 28, 2025

(30) Foreign Application Priority Data
Nov. 20, 2023 (JP) 2023-196623

(51) Int. Cl. C08K 3/08; C08J 5/18; C08L 63/04; H01F 1/20; H01F 27/28

(52) U.S. Cl. CPC C08K 3/08; C08J 5/18; C08L 63/04; H01F 1/20; H01F 27/2804; C08J 2363/04; C08J 2409/00; C08J 2433/04; C08K 2003/0856; C08K 2201/005; C08K 2201/01; C08L 2203/16; C08L 2203/20; C08L 2207/53

(57) ABSTRACT

A magnetic composition containing: a magnetic powder; a thermosetting component; and a rubber component, in which a 10% cumulative particle size on a volume basis of the magnetic powder is 0.6 to 2.0 μm, a 50% cumulative particle size on a volume basis of the magnetic powder is 1.1 to 3.6 μm, and a 90% cumulative particle size on a volume basis of the magnetic powder is 2.1 to 6.3 μm.

### TECHNICAL FIELD

The present disclosure relates to a magnetic composition, a magnetic film, a stack, and a circuit member.

### BACKGROUND ART

Materials containing metal powder having various physical properties are used according to the characteristics required for industrial products. For example, in fields such as inductors, electromagnetic wave shields, and bonded magnets, magnetic materials containing magnetic powder are used (see, for example, Patent Literature 1).

### CITATION LIST

### Patent Literature

Patent Literature 1: Japanese Unexamined Patent Publication No. 2014-127624

### SUMMARY OF INVENTION

### Technical Problem

Magnetic materials are required to have further improved magnetic properties, i.e., magnetic permeability. In addition, in recent years, with the miniaturization of circuit members such as inductors, the gaps between wiring of circuit members to which magnetic materials are applied have become even narrower, and it has become difficult to sufficiently fill the magnetic material between the wiring. Furthermore, when a magnetic material is used in a film form, the film-form magnetic material (magnetic film) needs to have flexibility for easy handling during manufacturing, cutting, use, and the like.

Therefore, an object of some aspects of the present disclosure is to provide a magnetic composition capable of forming a magnetic film that has a sufficiently high magnetic permeability, and is excellent in embeddability into gaps between wiring and has good flexibility, and a magnetic film composed of the magnetic composition. Another object of some aspects of the present disclosure is to provide a stack including the above-described magnetic film, and a circuit member including a layer composed of a cured product of the above-described magnetic composition.

### Solution to Problem

The present disclosure provides the following [1] to [9] in some aspects.

[1]

A magnetic composition containing: a magnetic powder; a thermosetting component; and a rubber component, wherein
a 10% cumulative particle size on a volume basis of the magnetic powder is 0.6 to 2.0 μm,
a 50% cumulative particle size on a volume basis of the magnetic powder is 1.1 to 3.6 μm, and
a 90% cumulative particle size on a volume basis of the magnetic powder is 2.1 to 6.3 μm.
   [2]

The magnetic composition according to [1], wherein a content of the magnetic powder is 70% by mass or more, based on a total mass of non-volatile content in the magnetic composition.

[3]

The magnetic composition according to [1] or [2], further containing particles containing the rubber component.

[4]

The magnetic composition according to any one of [1] to [3], wherein a content of the rubber component is 0.05 to 10.0% by mass, based on a total mass of non-volatile content in the magnetic composition.

[5]

The magnetic composition according to any one of [1] to [4], wherein the thermosetting component includes an epoxy group-containing compound and a phenolic curing agent.

[6]

A magnetic film composed of the magnetic composition according to any one of [1] to [5].

[7]

A stack including: a support; and the magnetic film according to [6], provided on the support.

[8]

A circuit member including: a substrate having a wiring provided on a surface thereof; and a magnetic layer filling a gap between the wiring on the substrate, wherein
the magnetic layer contains a cured product of the magnetic composition according to any one of [1] to [5].
   [9]

The circuit member according to [8], wherein the wiring is a coil wiring of an inductor.

### Advantageous Effects of Invention

According to some aspects of the present disclosure, it is possible to provide a magnetic composition capable of forming a magnetic film that has a sufficiently high magnetic permeability, and is excellent in embeddability into gaps between wiring and has good flexibility, and a magnetic film composed of the magnetic composition. Furthermore, according to some aspects of the present disclosure, it is possible to provide a stack including the above-described magnetic film, and a circuit member including a layer composed of a cured product of the above-described magnetic composition.

### BRIEF DESCRIPTION OF DRAWINGS

FIG. 1 is a schematic cross-sectional view showing an example of a method for manufacturing a circuit member according to an embodiment of the present disclosure.

### DESCRIPTION OF EMBODIMENTS

In the present specification, a numerical range indicated using “to” indicates a range including the numerical values described before and after “to” as the minimum value and the maximum value, respectively. Unless otherwise specified, the units of the numerical values described before and after “to” are the same. In the numerical ranges described stepwise in the present specification, the upper limit value or the lower limit value of a numerical range in one step may be replaced with the upper limit value or the lower limit value of a numerical range in another step. Furthermore, in the numerical ranges described in the present specification, the upper limit value or the lower limit value of the numerical range may be replaced with a value shown in the Examples. In addition, the individually described upper and lower limit values can be arbitrarily combined. “A or B” means that it may include either one of A and B, or may include both. Unless otherwise specified, the materials exemplified below may be used alone as one type, or two or more types may be used in combination. The content of each component in the composition means the total amount of the plurality of substances corresponding to each component present in the composition, unless otherwise specified, when a plurality of substances corresponding to each component exist in the composition.

Hereinafter, embodiments of the present disclosure will be described. However, the present disclosure is not limited to the following embodiments in any way.

### <Magnetic Composition>

A magnetic composition of one embodiment contains a magnetic powder, a thermosetting component, and a rubber component. In one embodiment, a 10% cumulative particle size on a volume basis of the magnetic powder (hereinafter referred to as “D₁₀”) is 0.6 to 2.0 μm, a 50% cumulative particle size on a volume basis of the magnetic powder (hereinafter referred to as “D₅₀”) is 1.1 to 3.6 μm, and a 90% cumulative particle size on a volume basis of the magnetic powder (hereinafter referred to as “D₉₀”) is 2.1 to 6.3 μm.

Here, D₁₀ means the particle size at which the cumulative volume from the smaller particle size side reaches 10% of the total volume of the magnetic powder in the volume-based particle size distribution of the magnetic powder. D₅₀ means the particle size at which the cumulative volume from the smaller particle size side reaches 50% of the total volume of the magnetic powder in the volume-based particle size distribution of the magnetic powder. D₉₀ means the particle size at which the cumulative volume from the smaller particle size side reaches 90% of the total volume of the magnetic powder in the volume-based particle size distribution of the magnetic powder. The particle size distribution used for calculating D₁₀, D₅₀, and D₉₀ of the magnetic powder can be obtained by performing a particle size distribution measurement using a laser diffraction/scattering particle size distribution analyzer under the conditions described in the Examples.

According to the magnetic composition of the above-described embodiment containing the magnetic powder having the above-described particle size distribution, it is possible to produce a magnetic film that is excellent in embeddability into narrow gaps between wiring (for example, gaps with a depth of 20 μm or more and a width of 25 μm or less). This is presumed to be an effect due to factors such as the particle size of the magnetic powder (particularly D₉₀) being sufficiently small to be able to enter the gaps between the wiring, and the particle size of the magnetic powder (particularly D₁₀) being sufficiently large so that the viscosity during heating and melting (melt viscosity) does not become too high. In addition, since the magnetic composition of the above-described embodiment includes the magnetic powder with the above-described particle size distribution, it has a sufficiently high magnetic permeability. In addition, since the magnetic composition of the above-described embodiment includes a rubber component, it has good flexibility while containing the magnetic powder having the above particle size distribution.

### (Magnetic Powder)

The magnetic powder is an aggregate of magnetic particles. The magnetic particles contain at least a magnetic component. The magnetic particles may contain one type of magnetic component alone, or may contain a plurality of types of magnetic components. The magnetic particles may consist only of a magnetic component, but may further contain components other than the magnetic component. The content of the magnetic component based on the total mass of the magnetic particles may be 20% by mass or more, 50% by mass or more, or 80% by mass or more.

The magnetic component, for example, contains a metal element. The metal element contained in the magnetic component may be, for example, at least one selected from the group consisting of base metal elements, noble metal elements, transition metal elements, and rare earth elements. The metal element may be, for example, at least one selected from the group consisting of iron (Fe), copper (Cu), titanium (Ti), manganese (Mn), cobalt (Co), nickel (Ni), zinc (Zn), niobium (Nb), aluminum (Al), tin (Sn), chromium (Cr), barium (Ba), strontium (Sr), lead (Pb), silver (Ag), praseodymium (Pr), neodymium (Nd), samarium (Sm), and dysprosium (Dy).

The magnetic component may be a simple metal consisting of only one type of metal element, or may be an alloy composed of two or more types of metal elements. The alloy may include at least one selected from the group consisting of a solid solution, a eutectic, and an intermetallic compound. The alloy may be, for example, a stainless steel such as an Fe—Cr-based alloy and an Fe—Ni—Cr-based alloy. It may also be a copper alloy such as a Cu—Sn-based alloy, a Cu—Sn—P-based alloy, a Cu—Ni-based alloy, and a Cu—Be-based alloy.

The magnetic component may be a powder of a metal compound containing the above-described metal element and an element other than the above-described metal element. The element other than the above-described metal element may be, for example, at least one selected from the group consisting of carbon (C), oxygen (O), beryllium (Be), phosphorus (P), boron (B), and silicon (Si). The metal compound may be, for example, a metal oxide such as iron oxide. The metal compound may be a sintered body having a metal oxide as a main component (for example, a sintered body formed by mixing and sintering a metal oxide and a metal element such as cobalt, nickel, and manganese).

The magnetic component may be a soft magnetic alloy or a ferromagnetic alloy. The magnetic component may be, for example, at least one selected from the group consisting of an Fe—Si-based alloy, an Fe—Si—Al-based alloy (Sendust), an Fe—Ni-based alloy (Permalloy), an Fe—Cu—Ni-based alloy (Permalloy), an Fe—Co-based alloy (Permendur), an Fe—Cr—Si-based alloy (electromagnetic stainless steel), an Nd—Fe—B-based alloy (rare earth magnet), an Sm—Fe—N-based alloy (rare earth magnet), an Al—Ni—Co-based alloy (Alnico magnet), and ferrite. The ferrite may be, for example, a spinel ferrite, a hexagonal ferrite, or a garnet ferrite.

From the viewpoint of obtaining higher magnetic permeability, the magnetic powder may include at least one powder selected from the group consisting of simple Fe and Fe-based alloys. The Fe-based alloy may be, for example, at least one selected from the group consisting of an Fe—Si-based alloy, an Fe—Si—Al-based alloy, an Fe—Ni-based alloy, an Fe—Cu—Ni-based alloy, an Fe—Co-based alloy, an Fe—Cr—Si-based alloy, an Fe—Si—B-based alloy, and an Fe—Si—B—P—Nb—Cr-based alloy. From the viewpoint of obtaining even higher magnetic permeability, the magnetic powder may include Fe amorphous alloy powder.

An Fe amorphous alloy is an amorphous powder obtained by rapidly cooling an alloy that is obtained by melting Fe as a main component at a high temperature together with other elements such as Si, and is also known as a metallic glass. Fe amorphous alloy powder can be produced in accordance with methods well known in the art. Fe amorphous alloy powder can also be obtained as a commercially available product. Examples include product names AW2-08 and KUAMET-6B2 manufactured by Epson Atmix Corporation, product names DAPMS3, DAPMS7, DAPMSA10, DAPPB, DAPPC, DAPMKV49, DAP410L, DAP430L, and DAPHYB series manufactured by Daido Steel Co., Ltd., and product names MH45D, MH28D, MH25D, and MH20D manufactured by Kobe Steel, Ltd. One of these Fe amorphous alloy powder may be used, or two or more may be used in combination.

The entire or a part of the surface of the magnetic powder may be coated with a surface treatment agent. The surface treatment agent may be, for example, an inorganic surface treatment agent such as an inorganic oxide, a phosphoric acid-based compound and a phosphate-based compound, and a silane coupling agent, an organic surface treatment agent such as montan wax, or a cured resin product. A coupling agent described later can also be used as the surface treatment agent.

The magnetic powder (for example, the magnetic powder containing an Fe-based alloy) may have its entire or a part of its surface coated with an insulating material. That is, the magnetic powder may contain magnetic particles whose surfaces are coated with an insulating material (hereinafter, “insulation-coated magnetic particles”). Examples of the insulating material include silica, titania, calcium phosphate, montan wax, and a cured product of epoxy resin. The insulation-coated magnetic particles may be Fe amorphous alloy powder having an insulating coating. The thickness of the inorganic oxide film constituting the insulating coating may be, for example, 1 to 100 nm.

As the insulation-coated magnetic particles, for example, “KUAMET9A4” (Fe—Si—B-based alloy, D₅₀: 20 μm, with insulating coating) manufactured by Epson Atmix Corporation, and “SAP-2DC” (Fe—Si—B—P—Nb—Cr-based alloy, D₅₀: 2.2 μm, with insulating coating) manufactured by Sintokogio, Ltd. can be used. These insulation-coated magnetic particles may be used in combination with magnetic particles having no insulating coating, and may be used in combination with, for example, soft ferrite powder “BSN-125” (Ni—Zn-based ferrite, D₅₀: 10 μm, without insulating coating) manufactured by Toda Kogyo Corp.

The shape of the magnetic particles is not particularly limited. The magnetic particles may be, for example, spherical, spheroidal, flat, plate-like, rod-like, and needle-like. From the viewpoint of further improving embeddability into gaps between wiring, the shape of the magnetic particles may be spherical. Here, the magnetic particles being spherical means that the average value of the aspect ratio, which is the ratio of the major axis to the minor axis (major axis/minor axis) of the magnetic particles measured by the following method, is 1.0 to 4.0. In the present specification, the average value of the aspect ratio is a value obtained by determining the ratio of the major axis to the minor axis (major axis/minor axis) for each of 100 randomly selected magnetic particles and averaging these obtained aspect ratios. The major axis of a magnetic particle means the distance between two parallel planes that circumscribe the magnetic particle and are selected such that the distance between them is maximized. The minor axis of a magnetic particle means the distance between two parallel planes that circumscribe the magnetic particle and are selected such that the distance between them is minimized. From the viewpoints of the fluidity and embeddability of the magnetic composition, and the dense packing of the magnetic particles, the aspect ratio may be 1.0 to 3.0, 1.0 to 2.0, or 1.0 to 1.5.

The D₁₀ of the magnetic powder is 0.6 μm or more, and from the viewpoint of the fluidity of the magnetic composition, it may be 0.7 μm or more, 0.95 μm or more, or 1.5 μm or more. The D₁₀ of the magnetic powder is 2.0 μm or less, and from the viewpoint of dense packing of the magnetic particles in the magnetic composition, it may be 1.9 μm or less, 1.4 μm or less, or 0.85 μm or less. From these viewpoints, the D₁₀ of the magnetic powder may be 0.7 to 1.9 μm, 0.95 to 1.4 μm, 1.5 to 2.0 μm, or 0.6 to 0.85 μm.

The D₅₀ of the magnetic powder is 1.1 μm or more, and from the viewpoints of the fluidity and magnetic permeability of the magnetic composition, it may be 1.2 μm or more, 1.5 μm or more, 2.0 μm or more, or 2.5 μm or more. The D₅₀ of the magnetic powder is 3.6 μm or less, and from the viewpoint of dense packing of the magnetic particles in the magnetic composition, it may be 3.5 μm or less, 3.0 μm or less, 2.4 μm or less, or 1.9 μm or less. From these viewpoints, the D₅₀ of the magnetic powder may be 1.2 to 3.5 μm, 1.5 to 3.0 μm, 2.0 to 2.4 μm, 2.5 to 3.6 μm, or 1.1 to 1.9 μm.

The D₉₀ of the magnetic powder is 2.1 μm or more, and from the viewpoints of the fluidity and magnetic permeability of the magnetic composition, it may be 2.2 μm or more, 2.8 μm or more, 3.6 μm or more, or 4.1 μm or more. The D₉₀ of the magnetic powder is 6.3 μm or less, and from the viewpoint of embeddability into gaps, it may be 6.0 μm or less, 5.0 μm or less, 4.5 μm or less, 4.0 μm or less, or 3.5 μm or less. From these viewpoints, the D₉₀ of the magnetic powder may be 2.2 to 6.0 μm, 2.8 to 5.0 μm, 3.6 to 4.5 μm, 4.1 to 6.3 μm, 2.1 to 4.0 μm, or 2.1 to 3.5 μm.

The magnetic powder having a particle size distribution as described above can be obtained by, for example, an atomization method, chemical vapor deposition (CVD), a liquid phase synthesis method, or the like. The particle size distribution of the magnetic powder produced by the above-described method may be adjusted using a milling machine, a ball mill, a bead mill, an air classifier, a wet sieving machine, a sieve, or the like. According to the method of adjusting to the target particle size distribution with a classifier, a sieve, or the like, compared to the method of adjusting the particle size distribution by applying force to particles and pulverizing them with a milling machine, a ball mill, or the like, the particle shape can be maintained as spherical, so it is easy to obtain a magnetic powder with excellent fluidity, and since structural defects and crystal strain at the interface generated by pulverization are less likely to occur, it is easy to obtain a magnetic powder with excellent magnetic permeability.

From the viewpoint of obtaining higher magnetic permeability, the content of the magnetic powder may be 70% by mass or more, 75% by mass or more, or 80% by mass or more, based on the total mass of the non-volatile content in the magnetic composition. From the viewpoint of further improving embeddability into gaps between wiring, the content of the magnetic powder may be 97% by mass or less, 95% by mass or less, or 93% by mass or less, based on the total mass of the non-volatile content in the magnetic composition. From these viewpoints, the content of the magnetic powder may be 70 to 97% by mass, 75 to 95% by mass, or 80 to 93% by mass, based on the total mass of the non-volatile content in the magnetic composition. Here, the non-volatile content in the magnetic composition means components other than volatile components among the components contained in the magnetic composition. The volatile component refers to a component that shows a mass reduction of 10% by mass or more when heated at 180° C. for 60 minutes and a component having a boiling point of 300° C. or lower.

### (Thermosetting Component)

The thermosetting component includes, for example, a thermosetting compound. The thermosetting component may further include a curing agent for the thermosetting compound, and may further include a curing accelerator.

### [Thermosetting Compound]

The thermosetting compound is, for example, a compound that cures by heat treatment alone or by reacting with a curing agent. The thermosetting compound may be a monomer, or may be a compound (oligomer or polymer) having a structural unit formed by polymerization of a monomer, which is generally called a thermosetting resin. From the viewpoint of enhancing the shape retention of the magnetic film, which is a molded body of the magnetic composition, the thermosetting compound may include a thermosetting resin.

The thermosetting resin can function as a binder resin that binds the magnetic powder. Examples of the thermosetting resin include epoxy resin, phenolic resin, acrylic resin, polyimide resin, polyamide-imide resin, and the like.

The weight-average molecular weight of the thermosetting resin is, for example, 150 or more, and may be 400 to 1,000,000. The weight-average molecular weight in the present specification is a value in terms of standard polystyrene, measured by a gel permeation chromatography (GPC) method.

The content of the thermosetting resin may be, for example, 100% by mass, or may be 0 to 99% by mass, 10 to 98% by mass, or 20 to 97% by mass, based on the total mass of the thermosetting compound.

From the viewpoint of enhancing curability, the thermosetting compound may include a compound having one or more epoxy groups in the molecule (hereinafter, referred to as an “epoxy group-containing compound”). The content of the epoxy group-containing compound may be, for example, 100% by mass, or may be 0 to 99% by mass, 20 to 95% by mass, or 30 to 90% by mass, based on the total mass of the thermosetting compound.

As the epoxy group-containing compound, a compound generally known as an epoxy resin (for example, an oligomer and polymer having two or more epoxy groups in the molecule) can be used. Examples of such a compound include at least one selected from the group consisting of a biphenyl type epoxy resin, a stilbene type epoxy resin, a diphenylmethane type epoxy resin, a sulfur atom-containing type epoxy resin, a novolac type epoxy resin, a biphenyl novolac type epoxy resin, a dicyclopentadiene type epoxy resin, a salicylaldehyde type epoxy resin, a copolymer type epoxy resin of naphthols and phenols, an epoxidized product of an aralkyl type phenolic resin, a bisphenol type epoxy resin, a glycidyl ether type epoxy resin of alcohols, a glycidyl ether type epoxy resin of a para-xylylene and/or meta-xylylene modified phenolic resin, a glycidyl ether type epoxy resin of a terpene-modified phenolic resin, a cyclopentadiene type epoxy resin, a glycidyl ether type epoxy resin of a polycyclic aromatic ring-modified phenolic resin, a glycidyl ether type epoxy resin of a naphthalene ring-containing phenolic resin, a glycidyl ester type epoxy resin, a glycidyl type or methylglycidyl type epoxy resin, an alicyclic type epoxy resin, a halogenated phenol novolac type epoxy resin, a hydroquinone type epoxy resin, a trimethylolpropane type epoxy resin, and a linear aliphatic epoxy resin obtained by oxidizing an olefin bond with a peracid such as peracetic acid. Among these, from the viewpoint of further enhancing curability, a biphenyl novolac type epoxy resin may be used. The content of the epoxy resin may be, for example, 10 to 100% by mass, 20 to 100% by mass, or 30 to 100% by mass, based on the total mass of the epoxy group-containing compound.

As the epoxy group-containing compound, a compound generally known as a reactive diluent (for example, an epoxy group-containing compound with a molecular weight of 100 to 700) may also be used. As such a compound, at least one selected from the group consisting of n-butyl glycidyl ether, versatic acid glycidyl ether, styrene oxide, ethylhexyl glycidyl ether, phenyl glycidyl ether, butylphenyl glycidyl ether, 1,6-hexanediol diglycidyl ether, neopentyl glycol diglycidyl ether, diethylene glycol diglycidyl ether, and trimethylolpropane triglycidyl ether may be used. The content of the epoxy group-containing compound with a molecular weight of 100 to 700 may be, for example, 0 to 95% by mass, 0 to 80% by mass, or 0 to 60% by mass, based on the total mass of the epoxy group-containing compound.

The epoxy group-containing compound may include an epoxy group-containing compound that is liquid at 25° C. “Being liquid at 25° C.” means that the viscosity of the epoxy group-containing compound at 25° C. is 200 Pa·s or less. The above-described viscosity is a value measured using an E-type viscometer under the conditions of temperature: 25° C., rotor: SPP, and rotation speed: 2.5 rpm. Examples of the epoxy group-containing compound that is liquid at 25° C. include bisphenol type liquid epoxy resins such as bisphenol A type liquid epoxy resin, bisphenol F type liquid epoxy resin, bisphenol AD type liquid epoxy resin, bisphenol S type liquid epoxy resin, and hydrogenated bisphenol A type liquid epoxy resin; naphthalenediol type liquid epoxy resin; aminoglycidyl ether type liquid epoxy resin; and phenol novolac type liquid epoxy resin. The epoxy group-containing compound that is liquid at 25° C. may be one that has been blended as a dispersion medium for rubber particles described later. As the epoxy group-containing compound that is liquid at 25° C., at least one selected from the group consisting of a bisphenol type liquid epoxy resin and a phenol novolac type liquid epoxy resin may be used from the viewpoint of enhancing the flexibility and embeddability of the magnetic film. The content of the epoxy group-containing compound that is liquid at 25° C. may be, for example, 0 to 100% by mass, 10 to 90% by mass, or 20 to 80% by mass, based on the total mass of the epoxy group-containing compound.

As the epoxy group-containing compound, an epoxy group-containing compound that is liquid at 25° C. and an epoxy group-containing compound that is non-liquid (solid) at 25° C. may be used in combination. In this case, as the epoxy group-containing compound that is non-liquid (solid) at 25° C., a biphenyl novolac type epoxy resin may be used from the viewpoint of further enhancing curability. Note that “being non-liquid (solid) at 25° C.” means that the viscosity of the epoxy group-containing compound at 25° C. is more than 200 Pa·s.

The epoxy equivalent of the epoxy group-containing compound may be 80 to 500 g/eq, 100 to 400 g/eq, or 150 to 350 g/eq. The epoxy equivalent of the epoxy group-containing compound can be measured in accordance with JIS K 7236. When the thermosetting compound includes a plurality of types of epoxy group-containing compounds, the epoxy equivalent measured for a mixture of all the epoxy group-containing compounds may be within the above-described range.

### [Curing Agent]

As the curing agent, a known curing agent corresponding to the thermosetting compound can be used. For example, when the thermosetting compound is an epoxy group-containing compound, a compound that reacts with the epoxy groups of the epoxy group-containing compound to form a cured product can be used. Specific examples of the curing agent for the epoxy group-containing compound include a phenolic curing agent, an acid anhydride-based curing agent, an amine-based curing agent, an imidazole-based curing agent, and an imidazoline-based curing agent. Among these, from the viewpoint of enhancing curability, a phenolic curing agent may be used. Note that an amine-based curing agent (more specifically, a tertiary amine), an imidazole-based curing agent, and an imidazoline-based curing agent can also be used as a curing accelerator in combination with another curing agent (for example, a phenolic curing agent).

The phenolic curing agent is a compound having at least two phenolic groups in the molecule. Examples of the phenolic curing agent include: novolac type phenolic resins obtained by condensing or co-condensing phenols such as phenol, cresol, resorcin, catechol, bisphenol A, bisphenol F, phenylphenol, and aminophenol and/or naphthols such as α-naphthol, β-naphthol, and dihydroxynaphthalene with aldehydes such as formaldehyde, benzaldehyde, and salicylaldehyde under an acidic catalyst; aralkyl type phenolic resins such as a phenol-aralkyl resin synthesized from phenols and/or naphthols and dimethoxyparaxylene or bis(methoxymethyl) biphenyl, a biphenylene type phenol-aralkyl resin, and a naphthol-aralkyl resin; a dicyclopentadiene type phenolic resin synthesized by copolymerization of phenols and/or naphthols with dicyclopentadiene; a triphenylmethane type phenolic resin; a terpene-modified phenolic resin; a para-xylylene and/or meta-xylylene modified phenolic resin; a melamine-modified phenolic resin; and phenolic resins obtained by copolymerizing two or more of these. Among these, from the viewpoint of further enhancing curability, a novolac type phenolic resin may be used.

The content of the curing agent can be set in consideration of the ratio between the number of equivalents of reactive groups in the thermosetting compound and the number of equivalents of active groups in the curing agent that react with the reactive groups. The number of equivalents of active groups in the curing agent per 1 equivalent of reactive groups in the thermosetting compound may be 0.5 to 1.5 equivalents, 0.9 to 1.4 equivalents, or 1.0 to 1.2 equivalents. This ratio can be said to be, for example, when an epoxy-containing compound is used as the thermosetting compound and a phenolic curing agent is used as its curing agent, the number of equivalents of phenolic hydroxyl groups in the phenolic curing agent per 1 equivalent of epoxy groups in the epoxy group-containing compound. When the above-described ratio is 0.5 equivalents or more, effects such as suppression of a decrease in curing speed, suppression of a decrease in the glass transition temperature and elastic modulus of the resulting cured product, and suppression of a decrease in the insulation reliability of the cured product due to unreacted components are expected. When the above-described ratio is 1.5 equivalents or less, effects such as suppression of a decrease in the mechanical strength of the resulting cured product and suppression of a decrease in the insulation reliability of the cured product due to unreacted components are expected. However, in the above-described embodiment, the ratio of active groups of the curing agent (the number of equivalents of active groups in the curing agent per 1 equivalent of reactive groups in the thermosetting compound) is not limited, and the effects according to the present disclosure can be obtained even if the ratio is outside the above-described range.

### [Curing Accelerator]

The curing accelerator is not limited as long as it is a compound that can accelerate the curing reaction between the thermosetting compound and the curing agent (for example, the curing reaction between the epoxy group-containing compound and the phenolic curing agent). Examples of the curing accelerator include a tertiary amine, an imidazole-based curing accelerator, an imidazoline-based curing accelerator, and a phosphorus compound. Among these, from the viewpoint of enhancing the curing acceleration effect, an imidazole-based curing accelerator may be used.

The imidazole-based curing accelerator is a compound having an imidazole skeleton, and may be an imidazole-based compound in which a hydrogen atom in the molecule is substituted with a substituent. The imidazole-based curing accelerator may be a compound having an imidazole skeleton, such as an alkyl group-substituted imidazole. Examples of the imidazole-based curing accelerator include imidazole, 2-methylimidazole, 2-ethylimidazole, 2-ethyl-4-methylimidazolepropanenitrile, 1-cyanoethyl-2-phenylimidazole, and 2-isopropylimidazole. As the imidazole-based curing accelerator, 2-ethyl-4-methylimidazole (for example, “CUREZOL 2E4MZ” manufactured by Shikoku Chemicals Corporation) may be used from the viewpoint of further enhancing the curing acceleration effect.

The content of the curing accelerator is not particularly limited as long as it is an amount that provides a curing acceleration effect. The content of the curing accelerator may be, for example, 0.001 parts by mass or more, 0.01 parts by mass or more, or 0.1 parts by mass or more, and 5 parts by mass or less, 4 parts by mass or less, or 3 parts by mass or less, with respect to 100 parts by mass in total of the thermosetting compound and the curing agent. When the content of the curing accelerator is 0.001 parts by mass or more, a sufficient curing acceleration effect can be easily obtained. When the content of the curing accelerator is 5 parts by mass or less, excellent storage stability as a magnetic composition can be easily obtained. However, the effects according to the present disclosure can be obtained even when the content of the curing accelerator is outside the above-described range. Note that the curing accelerator may be contained as a curing agent, but in this case, the component with the smaller content shall be regarded as the curing accelerator.

From the viewpoint of obtaining a cured product having higher heat resistance, the content of the thermosetting component may be 3% by mass or more, 4% by mass or more, or 5% by mass or more, based on the total mass of the non-volatile content in the magnetic composition. From the viewpoint of obtaining higher magnetic permeability, the content of the thermosetting component may be 30% by mass or less, 25% by mass or less, or 20% by mass or less, based on the total mass of the non-volatile content in the magnetic composition. From these viewpoints, the content of the thermosetting component may be 3 to 30% by mass, 4 to 25% by mass, or 5 to 20% by mass, based on the total mass of the non-volatile content in the magnetic composition.

### (Rubber Component)

The rubber component is a compound having rubber elasticity, called a thermosetting elastomer or a thermoplastic elastomer, and specifically, is a compound having a Young's modulus of 0.01 to 100 as measured by a dynamic mechanical analysis apparatus. Such a rubber component contributes to improving the flexibility of the magnetic film, which is a molded body of the magnetic composition, and its cured product.

Examples of the rubber component include acrylic rubber, isoprene rubber, butyl rubber, styrene-butadiene rubber, butadiene rubber, acrylonitrile-butadiene rubber, silicone rubber, urethane rubber, chloroprene rubber, ethylene-propylene rubber, fluororubber, vulcanized rubber, epichlorohydrin rubber, chlorinated butyl rubber, and the like. As the rubber component, a block copolymer such as an acrylic-based block copolymer (for example, a block copolymer having a block structure of polymethyl methacrylate-polybutyl acrylate-polymethyl methacrylate) or a styrenic block copolymer (for example, a block copolymer having a block structure of polystyrene-polybutylene-polyethylene-polystyrene) can also be used. Among these, at least one selected from the group consisting of butadiene rubber, silicone rubber, styrene-butadiene rubber, and acrylic rubber may be used from the viewpoint of further enhancing the flexibility of the magnetic film and its cured product and embeddability into gaps between wiring.

The magnetic composition may contain particles containing the above-described rubber component (rubber particles). When the rubber component in the magnetic composition exists as particles without being dissolved in the thermosetting component, the magnetic composition tends to have a lower melt viscosity and tends to be more excellent in embeddability into gaps between wiring, as compared to the case where the rubber component exists in a state dissolved in the thermosetting component. For the same reason, it becomes possible to increase the blending amount of the magnetic powder, which makes it easier to obtain a higher magnetic property. The rubber particles may be composed only of the rubber component, but may further contain components other than the rubber component. The content of the rubber component in the rubber particles may be 40% by mass or more, 60% by mass or more, or 80% by mass or more, based on the total mass of the rubber particles.

The rubber particles may have a core-shell structure. The rubber particles having a core-shell structure may be, for example, particles having a core layer composed of a rubber component and a shell layer composed of a resin. Examples of the resin include an epoxy-based resin composed of a polymer containing an epoxy group-containing monomer as a monomer unit (for example, a resin composed of a homopolymer of an epoxy group-containing monomer, a resin composed of a copolymer of an epoxy group-containing monomer and an alkyl (meth)acrylate monomer or other copolymerizable monomer), and an acrylic-based resin composed of a polymer containing an alkyl (meth)acrylate monomer as a monomer unit (for example, a resin composed of a homopolymer of an alkyl (meth)acrylate monomer, a resin composed of a copolymer of an alkyl (meth)acrylate monomer and an epoxy group-containing monomer or other copolymerizable monomer). By forming a shell layer around the core layer, it is possible to improve the dispersibility and fluidity of the rubber particles.

Examples of the epoxy group-containing monomer include allyl glycidyl ether, glycidyl (meth)acrylate, and the like. Examples of the alkyl acrylate monomer include methyl (meth)acrylate, ethyl (meth)acrylate, propyl (meth)acrylate, butyl (meth)acrylate, ethylhexyl (meth)acrylate, and the like. Examples of other copolymerizable monomers include styrene, α-methylstyrene, 1,4-divinylbenzene, 1- or 2-vinylnaphthalene, (meth)acrylonitrile, 2-methoxyethyl (meth)acrylate, 2-ethoxyethyl (meth)acrylate, and the like. The resin constituting the shell layer may be a copolymer containing glycidyl methacrylate, methyl methacrylate, and styrene as monomer units from the viewpoints of storage stability, viscosity, toughness, and adhesion.

The core layer and the shell layer may have a multilayer structure. In that case, the composition may be different in each layer. An adhesive layer may also be present between the core layer and the shell layer.

From the viewpoints of flexibility and fluidity, the average particle diameter of the rubber particles may be 10 nm or more, 30 nm or more, 40 nm or more, or 50 nm or more. From the viewpoints of heat resistance, strength, flexibility, uniformity of magnetic properties, and embeddability of the magnetic composition, the average particle diameter of the rubber particles may be 2000 nm or less, 1000 nm or less, or 500 nm or less. From these viewpoints, the average particle diameter of the rubber particles may be 10 to 2000 nm, 30 to 2000 nm, 40 to 1000 nm, or 50 to 500 nm. The average particle diameter is the 50% cumulative particle size on a volume basis, measured in the same manner as D₅₀ of the magnetic powder.

From the viewpoint of further improving the flexibility of the magnetic film and its cured product, as well as the magnetic permeability, the content of the rubber component in the magnetic composition may be 0.05% by mass or more, 0.1% by mass or more, 0.3% by mass or more, or 0.5% by mass or more, based on the total mass of the non-volatile content in the magnetic composition. From the viewpoint of further improving the adhesion, magnetic properties, low thermal expansion, chemical resistance, and embeddability into gaps between wiring of the magnetic composition, the content of the rubber component may be 10.0% by mass or less, 5.0% by mass or less, or 3.0% by mass or less, based on the total mass of the non-volatile content in the magnetic composition. From these viewpoints, the content of the rubber component may be 0.05 to 10.0% by mass, 0.1 to 10.0% by mass, 0.3 to 5.0% by mass, or 0.5 to 3.0% by mass, based on the total mass of the non-volatile content in the magnetic composition. In the present embodiment, the content of the rubber particles may be within the above-described range.

### (Other Components)

The magnetic composition may further contain components other than the magnetic powder, the thermosetting component, and the rubber component (other components). Examples of other components include a thermoplastic resin, a coupling agent, a flame retardant, and the like.

### [Thermoplastic Resin]

The thermoplastic resin may be, for example, at least one selected from the group consisting of acrylic resin, polyethylene, polypropylene, polystyrene, polyvinyl chloride, and polyethylene terephthalate. The content of the thermoplastic resin may be, for example, 0.01 to 1.0% by mass based on the total mass of the non-volatile content in the magnetic composition.

### [Coupling Agent]

The coupling agent contributes to improving the dispersibility of the magnetic powder, improving the adhesion between the thermosetting component and the magnetic powder, and improving the adhesion to a substrate, flexibility, and mechanical strength of the cured product obtained from the magnetic composition. The coupling agent may be, for example, at least one selected from the group consisting of a silane-based compound (silane coupling agent), a titanium-based compound, an aluminum compound (aluminum chelates), and an aluminum/zirconium-based compound. From the viewpoint of enhancing the effect as the coupling agent, the coupling agent may be a silane coupling agent, and may be at least one selected from the group consisting of epoxysilane, mercaptosilane, aminosilane, alkylsilane, ureidosilane, acid anhydride-based silane, and vinylsilane. Among these, when an aminosilane is used, the above-described effects can be further enhanced. Examples of the aminosilane include 3-aminopropyltrimethoxysilane (such as KBM-903 manufactured by Shin-Etsu Chemical Co., Ltd.), 3-aminopropyltriethoxysilane (such as KBE-903 manufactured by Shin-Etsu Chemical Co., Ltd.), N-2-(aminoethyl)-3-aminopropyltrimethoxysilane (such as KBM-603 manufactured by Shin-Etsu Chemical Co., Ltd.), N-2-(aminoethyl)-8-aminooctyltrimethoxysilane (such as KBM-6803 manufactured by Shin-Etsu Chemical Co., Ltd.), N-2-(aminoethyl)-3-aminopropyltriethoxysilane (such as KBE-603 manufactured by Shin-Etsu Chemical Co., Ltd.), N-phenyl-3-aminopropyltrimethoxysilane (such as KBM-573 manufactured by Shin-Etsu Chemical Co., Ltd.), N-2-(aminoethyl)-3-aminopropylmethyldimethoxysilane (such as KBM-602 manufactured by Shin-Etsu Chemical Co., Ltd.), N-2-(aminoethyl)-3-aminopropylmethyldiethoxysilane (such as KBE-602 manufactured by Shin-Etsu Chemical Co., Ltd.), N-(vinylbenzyl)-2-aminoethyl-3-aminopropyltrimethoxysilane (such as KBM-575 manufactured by Shin-Etsu Chemical Co., Ltd.), 3-triethoxysilyl-N-(1,3-dimethyl-butylidene) propylamine (such as KBE-9103P manufactured by Shin-Etsu Chemical Co., Ltd.), and X-12-972F (product name, manufactured by Shin-Etsu Chemical Co., Ltd.). The content of the coupling agent may be, for example, 0.01 to 1.0% by mass, based on the total mass of the non-volatile content in the magnetic composition.

### [Flame Retardant]

The flame retardant contributes to the environmental safety, recyclability, molding processability, cost reduction, and the like of the magnetic composition. The flame retardant may be, for example, at least one selected from the group consisting of a bromine-based flame retardant, a phosphorus-based flame retardant, a hydrated metal compound-based flame retardant, a silicone-based flame retardant, a nitrogen-containing compound, a hindered amine compound, an organometallic compound, and an aromatic engineering plastic. The content of the flame retardant may be, for example, 0.01 to 0.5% by mass based on the total mass of the non-volatile content in the magnetic composition.

In the present embodiment, since the magnetic powder having the above-described particle size distribution is used, the magnetic composition tends to exhibit a sufficiently low minimum melt viscosity. The minimum melt viscosity of the magnetic composition is, for example, 10,000 Pa·s or less (for example, 50 to 10,000 Pas) at 120° C. The minimum melt viscosity of the magnetic composition can also be appropriately adjusted by the type and amount of the thermosetting component, rubber component, and the like. The minimum melt viscosity of the magnetic composition may be 50 to 5000 Pa·s or 50 to 3000 Pas. The minimum melt viscosity of the magnetic composition means the minimum value of the shear viscosity measured by dynamic viscoelastic measurement of the magnetic composition.

The magnetic composition of the present embodiment, for example, has insulating properties. The electrical resistivity of the magnetic composition, as measured by a resistivity meter, may be 10⁷ Ω·cm or more, 10⁸ Ω·cm or more, or 10⁹ Ω·cm or more. A magnetic composition having such an electrical resistivity can be easily obtained by using an insulating thermosetting component.

### <Magnetic Film>

A magnetic film of one embodiment is composed of the magnetic composition of the above-described embodiment. That is, the magnetic film of one embodiment contains a magnetic powder having a D₁₀ of 0.6 to 2.0 μm, a D₅₀ of 1.1 to 3.4 μm, and a D₉₀ of 2.1 to 6.3 μm, a thermosetting component, and a rubber component. Therefore, the magnetic film of one embodiment is excellent in embeddability into gaps between wiring.

The magnetic film may be in a film form or a sheet form. The thickness of the magnetic film is, for example, 5 to 200 μm. The thickness of the magnetic film may be 0.2 times or more, 0.4 times or more, or 0.6 times or more of the depth of the gap between wiring into which the magnetic composition is embedded.

The magnetic film can be formed, for example, by mixing and stirring the magnetic powder (the magnetic powder having the above-described particle size distribution), the thermosetting component, the rubber component, and other components blended as necessary, together with an organic solvent to prepare a liquid composition for forming a magnetic film (for example, a paste), coating the liquid composition on a support, and drying it.

As the organic solvent, for example, an organic solvent capable of dissolving the thermosetting component can be used. As the organic solvent, one that dissolves the thermosetting component while does not dissolve the rubber component may be used. The organic solvent may be, for example, at least one selected from the group consisting of acetone, methyl ethyl ketone, methyl isobutyl ketone, benzene, toluene, carbitol acetate, butyl carbitol acetate, cyclohexanone, and xylene. From the viewpoint of workability, the organic solvent may be liquid at room temperature (25° C.). From the viewpoint of workability, the boiling point of the organic solvent may be 50° C. or higher and 160° C. or lower.

As the support, a polymer film (support film) having heat resistance and solvent resistance, such as a polyester like polyethylene terephthalate (PET), or a polyolefin like polypropylene or polyethylene, can be used. A metal foil such as a copper foil can also be used as the support. Among them, a PET film may be used because it is easily available and has excellent handling properties (particularly heat resistance, thermal shrinkage rate, and breaking strength) in the producing process. The thickness of the support is, for example, 1 to 150 μm. The surface of the support may be subjected to a release treatment.

A cover film may be attached onto the magnetic film as necessary. That is, the present disclosure, as another embodiment, provides a stack including a magnetic film and a cover film provided on the magnetic film. As the cover film, a polymer film (support film) having heat resistance and solvent resistance, such as a polyester like polyethylene terephthalate (PET), or a polyolefin like polypropylene or polyethylene, can be used. Among them, a PET or polyethylene film may be used because it is easily available and has excellent handling properties (particularly, heat resistance, thermal shrinkage rate, breaking strength, and releasability) during the producing process and product use. The thickness of the cover film is, for example, 20 to 100 μm. The surface of the cover film may be subjected to a release treatment.

The method of stirring is not particularly limited, and for example, a stirring blade, planetary mixing, a roll mill, a disk mill, and a ball mill can be used.

The drying may be performed under conditions that allow the organic solvent to volatilize while not allowing the curing of the thermosetting component to proceed. The drying temperature may be, for example, 60 to 180° C. The drying time may be, for example, 2 to 45 minutes.

The magnetic film obtained after drying may contain an organic solvent, but the content of the organic solvent may be 5% by mass or less, 3% by mass or less, or 1% by mass or less, based on the total mass of the magnetic film (that is, the total mass of the magnetic composition). The magnetic film may be substantially free of organic solvent. That is, it may be 0.5% by mass or less based on the total mass of the magnetic film.

The magnetic film described above is used, for example, for a circuit member (such as a circuit member including an inductor) whose characteristics are expected to be improved by a magnetic material. Since the magnetic film is excellent in embeddability into gaps between wiring, it may be used for the purpose of filling the gaps of a circuit member having narrow gaps between wiring (for example, a gap with a depth of 20 μm or more and a width of 20 μm or less). However, the magnetic film can be used not only for the gaps between the wiring (for example, the gaps between the wiring of a circuit member including an inductor) but also for applications such as coating the periphery of a circuit member, and as a core material. The magnetic film can also be used for applications such as crosstalk suppression, antenna-in-package, and electromagnetic wave shielding.

### <Stack>

A stack of one embodiment includes a support and a magnetic film provided on the support. The stack is, for example, in a sheet form or a film form. Details of the support and the magnetic film are as exemplified above. The stack may be used for manufacturing a circuit member described later. The stack may further include a layer other than the support and the magnetic film. For example, to prevent scratches, dirt, deterioration, and sticking of the magnetic film, a cover film may be provided on the magnetic film. Details of the cover film are as exemplified above.

### <Circuit Member>

A circuit member of one embodiment includes a substrate having a wiring provided on a surface thereof, and a magnetic layer filling a gap between the wiring on the substrate.

The substrate is, for example, a wiring substrate (circuit board) including a substrate and a wiring (circuit) provided on the surface of the substrate. Examples of the substrate include a substrate of an inorganic material such as a semiconductor, glass, ceramic, or a magnetic material, a substrate of an organic material such as polyimide or polycarbonate, and a substrate containing an inorganic substance and an organic substance such as glass/epoxy. The wiring is formed of, for example, gold, silver, copper, or the like. The minimum value of the wiring spacing (the width of the gap between adjacent wirings) may be 5 μm or less (for example, 1 to 400 μm). The height of the wiring (the depth of the gap with the above-described width) may be 5 μm or more (for example, 1 to 200 μm), and may be 20 μm or more or 90 μm or more.

The magnetic layer contains a cured product of the magnetic composition of the above-described embodiment. The magnetic layer is, for example, a cured product of the magnetic film of the above-described embodiment. The thickness of the magnetic layer is, for example, 5 to 200 μm.

The circuit member of the embodiment may be, for example, an inductor, or may be an intermediate member for manufacturing an inductor. In either case, the magnetic layer is provided to fill a gap between coil wiring of the inductor.

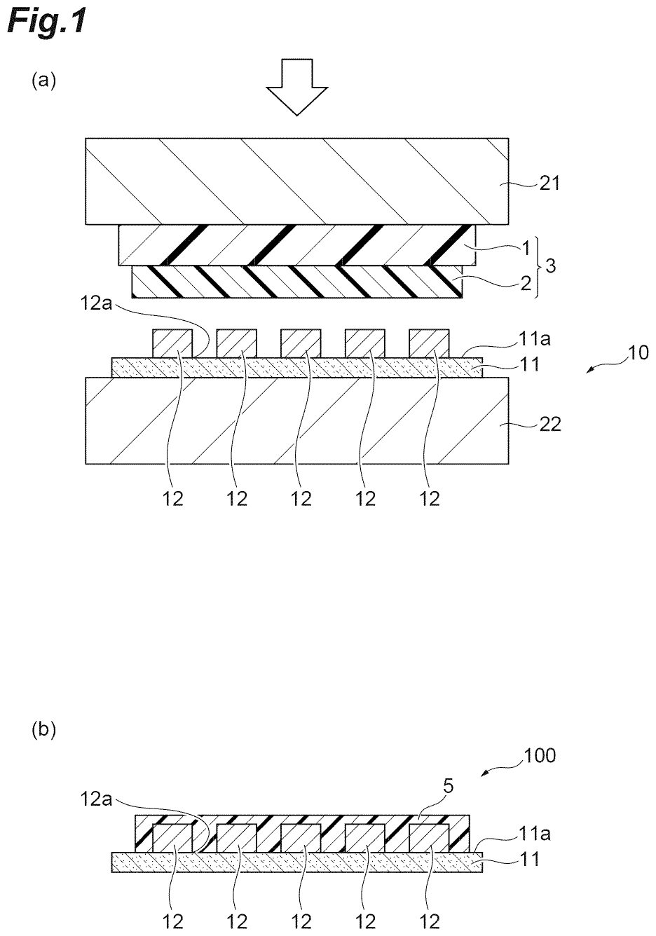

FIG. 1 is a schematic cross-sectional view showing an example of a method for manufacturing the circuit member of the above-described embodiment. A method for manufacturing a circuit member of one embodiment includes: a step of preparing a stack 3 including a support 1 and a magnetic film 2 provided on the support 1, and a wiring substrate 10 including a substrate 11 and a wiring 12 provided on a surface 11a of the substrate 11; a step of pressure-bonding the magnetic film 2 to the wiring substrate 10 so as to cover the wiring 12 (pressure-bonding step); and a step of heating and curing the layer composed of the magnetic film 2 (heating and curing step). According to this method, a gap 12a between the wiring 12 of the wiring substrate 10 is filled with the layer composed of the magnetic film 2, and a circuit member 100 is obtained, which includes the wiring substrate 10 and a magnetic layer 5 formed by curing the layer composed of the magnetic film 2. Note that the support 1 may be removed during lamination of the magnetic film 2, may be removed after lamination and before heating and curing the layer composed of the magnetic film 2, or may be removed after obtaining the magnetic layer 5.

The method for disposing the magnetic film 2 on the wiring substrate 10 is not particularly limited, but for example, as shown in FIG. 1, a laminating apparatus including an upper heater 21 and a lower heater 22 can be used. In the method shown in FIG. 1, first, the wiring substrate 10 is placed on the lower heater 22 side between the upper heater 21 and the lower heater 22 such that the surface on the wiring 12 side faces the upper heater 21 side, and the stack 3 is placed on the upper heater 21 side between the upper heater 21 and the lower heater 22 such that the magnetic film 2 faces the lower heater 22 side (see (a) of FIG. 1). Next, the laminating apparatus is operated, and while heating the stack 3 and the wiring substrate 10, the stack 3 is pressed from the upper heater 21 side in a direction facing the wiring substrate 10 (the direction of the arrow in (a) of FIG. 1), thereby pressure-bonding the magnetic film 2 to the wiring substrate 10.

As the laminating apparatus, for example, a vacuum laminating apparatus such as a vacuum roll laminating apparatus can be used. The lamination can be performed, for example, under conditions of heating and pressing at 40 to 150° C. and 0.1 to 1.0 MPa for 0.5 to 10 minutes. Note that a pressing apparatus (for example, a vacuum pressing apparatus) can also be used instead of the laminating apparatus.

The heating in the heating and curing step can be performed, for example, under conditions of heating at 80 to 250° C. for 10 to 150 minutes in an inert gas atmosphere such as a nitrogen atmosphere. Heating may be performed in a vacuum atmosphere or in an air atmosphere.

In the above-described method, a part of the magnetic film 2 may be cured by the heating in the pressure-bonding step, and in this case, the pressure-bonding step is also included in the heating and curing step. However, the heating and curing step may include a second heating step of heating a partially cured product of the magnetic film 2, separately from the heating in the pressure-bonding step. The second heating step can be performed under conditions of heating at 80 to 250° C. for 10 to 150 minutes in an inert gas atmosphere such as a nitrogen atmosphere. Heating may be performed in a vacuum atmosphere or in an air atmosphere.

The circuit member 100 obtained by the above-described method is, for example, an intermediate member for manufacturing an inductor. The method for manufacturing the circuit member may further include steps such as via formation, desmear treatment, electroless plating treatment, and forming wiring with respect to the circuit member 100, and a circuit member such as an inductor may be obtained by repeating these steps multiple times. The wiring formation can be performed, for example, by a method of performing an electroless plating treatment, then forming a resist corresponding to a wiring pattern, performing an electrolytic copper plating treatment, and then performing resist stripping and flash etching.

### EXAMPLES

Hereinafter, the content of the present disclosure will be described in more detail using Examples and Comparative Examples, but the present disclosure is not limited to the following Examples.

### <Preparation of Magnetic Powder>

Magnetic powders A to G having the particle size distributions shown in Table 1 were prepared. The D₁₀, D₅₀, and D₉₀ of the magnetic powders were obtained by performing particle size distribution measurement under the following conditions using a laser diffraction/scattering particle size distribution analyzer.

### [Conditions]

Magnetic powder and cyclohexanone were weighed to prepare a dispersion of about 50% by mass of the magnetic powder. After dispersing the prepared dispersion for 90 seconds with an ultrasonic disperser, it was placed in a particle size distribution analyzer (LS 13 320 manufactured by Beckman Coulter, laser diffraction method) to measure the particle size distribution of the magnetic powder.

As magnetic powder A, metal glass magnetic powder “SAP-2DC” (Fe—Si—B—P—Nb—Cr-based alloy, with insulating coating) from Sintokogio, Ltd. was used.

Magnetic powder B was prepared by classifying magnetic powder A using a nylon mesh with a 1 μm opening to remove small-diameter magnetic powder.

Magnetic powder C was prepared by classifying magnetic powder A using a nylon mesh with a 1 μm opening and adding the obtained small-diameter magnetic powder to magnetic powder A.

Magnetic powder D was prepared by classifying magnetic powder A using a nylon mesh with a 1 μm opening and adding the obtained large-diameter magnetic powder to magnetic powder A.

Magnetic powder E was prepared by classifying magnetic powder A using a nylon mesh with a 3 μm opening and adding the obtained large-diameter magnetic powder to magnetic powder A.

Magnetic powder F was prepared by classifying magnetic powder A using a nylon mesh with a 5 μm opening and adding the obtained large-diameter magnetic powder to magnetic powder A.

As magnetic powder G, amorphous alloy powder “AW2-08” (Fe—Si—B—Cr-based alloy, with insulating coating) from Epson Atmix Corporation was used.

TABLE 1

| | Magnetic | Magnetic | Magnetic | Magnetic | Magnetic | Magnetic | Magnetic |
|---|---|---|---|---|---|---|---|
| | Powder A | Powder B | Powder C | Powder D | Powder E | Powder F | Powder G |
| D₁₀ | 1.10 | 1.81 | 0.70 | 0.35 | 1.75 | 1.89 | 1.82 |
| D₅₀ | 2.25 | 2.71 | 1.74 | 1.51 | 3.91 | 2.97 | 3.30 |
| D₉₀ | 3.93 | 4.27 | 3.22 | 3.18 | 5.92 | 6.56 | 5.34 |

### Example 1

5.00 g of “MX-136” manufactured by Kaneka Corporation (a mixture of a bisphenol type liquid epoxy resin and rubber particles having a core-shell structure dispersed in the resin (core layer: butadiene rubber, shell layer: acrylic resin), rubber particle content: 25% by mass), 7.50 g of solid epoxy resin “NC-3000-H” manufactured by Nippon Kayaku Co., Ltd. (biphenyl novolac type epoxy resin), 5.49 g of curing agent “HP-850N” manufactured by Resonac Corporation (novolac type phenolic resin), and 9.47 g of “cyclohexanone” manufactured by FUJIFILM Wako Pure Chemical Corporation were weighed respectively. These were put into a 250 ml ointment container as raw materials, and all the raw materials in the ointment container were stirred and kneaded with a planetary mixer. As the planetary mixer, “ARE-310” manufactured by THINKY CORPORATION was used. The stirring and kneading were performed twice for 20 minutes with the revolution speed of the planetary mixer set to 2000 rpm. Next, 0.090 g of curing accelerator “2E4MZ” (2-ethyl-4-methylimidazole) manufactured by Shikoku Chemicals Corporation was added to the mixture obtained by stirring and kneading, and the mixture was stirred and kneaded for 1 minute with the revolution speed of the planetary mixer set to 2000 rpm. Thereby, varnish X was obtained. The NV (non-volatile content) of the obtained varnish X was 65.6% by mass.

5.17 g of varnish X, 20.00 g of magnetic powder A, and 0.060 g of a silane coupling agent (“KBM-573” manufactured by Shin-Etsu Silicone Co., Ltd., N-phenyl-3-aminopropyltrimethoxysilane) were weighed respectively. These were put into a 50 ml ointment container as raw materials. All the raw materials in the ointment container were stirred and kneaded for 45 seconds at a revolution speed of 2000 rpm using a planetary mixer. Next, the raw materials in the ointment container were stirred using a spatula. Furthermore, a liquid composition (paste) for forming a magnetic film was prepared by stirring twice for 45 seconds at a revolution speed of 2000 rpm using the planetary mixer. The content of magnetic powder A based on the total mass of the non-volatile content of the obtained paste was 85.3% by mass.

The paste obtained above was coated on a PET film, which is a support, using a squeegee, and dried at 120° C. for 20 minutes to form a magnetic film. Thereby, a stack including the support and the magnetic film provided on the support was obtained.

### Example 2 to 4, Comparative Example 1 to 3

Liquid compositions (pastes) and stacks of Examples 2 to 4 and Comparative Examples 1 to 3 were obtained in the same manner as in Example 1, except that magnetic powders B to G were used instead of magnetic powder A, respectively.

### Example 5

A liquid composition (paste) and a stack of Example 5 were obtained in the same manner as in Example 1, except that the rubber component was changed from MX-136 to “MX-965” manufactured by Kaneka Corporation (a mixture of a bisphenol type liquid epoxy resin and rubber particles having a core-shell structure dispersed in the resin (core layer: silicone rubber, shell layer: acrylic resin), rubber particle content: 25% by mass).

### Comparative Example 4

A liquid composition (paste) and a stack of Comparative Example 4 were obtained in the same manner as in Example 1, except that the rubber component (MX-136) was not used, and the blending amount of the raw materials was adjusted so as to obtain a magnetic film composed of a magnetic composition having the composition shown in Table 2.

### <Evaluation 1>

### (Evaluation of Flexibility)

The magnetic films of Examples 1 to 5 and Comparative Examples 1 to 4 were wound around a 6 mm diameter rod, and visually checked for cracking of the magnetic film and peeling from the support. The case where there were neither cracking nor peeling was evaluated as good flexibility (A), and the case where there was either cracking or peeling was evaluated as poor (B). The evaluation results are shown in Table 2.

### <Evaluation 2>

The magnetic permeability of the magnetic layers produced using the magnetic films of Examples 1 to 5 and Comparative Examples 1 to 4, and the embeddability of the magnetic films were evaluated. The procedures for evaluating the magnetic permeability and embeddability are shown below, and the evaluation results are shown in Table 2.

### (Evaluation of Magnetic Permeability)

Magnetic films were stacked on each other by vacuum lamination to prepare a 1.1 mm thick magnetic film. A 1 mm thick stainless-steel plates were placed on all four sides around the magnetic film so as to surround the magnetic film. Using a vacuum press machine (manual hydraulic vacuum heating press, 1A31, manufactured by Imoto Machinery Co., Ltd.), the magnetic film was molded and cured into a 1 mm thick plate shape by pressing and heating at 180° C. and 2 MPa for 60 minutes under vacuum conditions to obtain a magnetic layer. The magnetic layer was formed into a ring-shaped sample with an outer diameter of 7 mm, an inner diameter of 3 mm, and a thickness of 1 mm by drilling, and the relative magnetic permeability u′ of the magnetic layer at 1 GHz was measured using the ring-shaped sample and a network analyzer.

### (Evaluation of Embeddability)

A groove with a width of 25 μm and a depth of 90 μm was formed in a silicon wafer by making a cut with a dicer. A magnetic film (stack) was placed on this wafer and pressed and heated at 120° C. and 0.5 MPa for 5 minutes using a vacuum laminator. The PET film, which is the support, was peeled off from the wafer in which the magnetic film was embedded, and the magnetic film was cured by heating at 180° C. for 60 minutes in a nitrogen atmosphere. The cured product was placed in an aluminum cup, fixed with a sample clip (SamplKlip, manufactured by Buehler), and epoxy resin (Epomount, manufactured by Refine Tec Co., Ltd.) was poured in and left at room temperature for 12 hours to cure the epoxy resin. Using a Refine Saw (RCA-005, manufactured by Refine Tec Co., Ltd.) equipped with a diamond cutting wheel (11-304, manufactured by Refine Tec Co., Ltd.), the cast sample was cut near the observation surface. The cross-section was polished with polishing paper to expose the observation surface, and the observation surface was further smoothed with alumina powder to obtain the observation surface. The cross-section of the sample was observed with a scanning electron microscope (SEM) (SU5000, manufactured by Hitachi High-Technologies Corporation). If the groove was filled with the magnetic composition to the bottom, the embeddability was evaluated as good (A), and if the magnetic composition did not fill to the bottom of the groove and there were voids, the embeddability was evaluated as poor (B).

TABLE 2

| | | | | | Comparative | Comparative | Comparative | | | Comparative |
|---|---|---|---|---|---|---|---|---|---|---|
| | | Example 1 | Example 2 | Example 3 | Example 1 | Example 2 | Example 3 | Example 4 | Example 5 | Example 4 |
| Composition | Magnetic | 85.3 | — | — | — | — | — | — | 85.3 | 85.3 |
| (parts by mass) | Powder A | | | | | | | | | |
| | Magnetic | — | 85.3 | — | — | — | — | — | — | — |
| | Powder B | | | | | | | | | |
| | Magnetic | — | — | 85.3 | — | — | — | — | — | — |
| | Powder C | | | | | | | | | |
| | Magnetic | — | — | — | 85.3 | — | — | — | — | — |
| | Powder D | | | | | | | | | |
| | Magnetic | — | — | — | — | 85.3 | — | — | — | — |
| | Powder E | | | | | | | | | |
| | Magnetic | — | — | — | — | — | 85.3 | — | — | — |
| | Powder F | | | | | | | | | |
| | Magnetic | — | — | — | — | — | — | 85.3 | — | — |
| | Powder G | | | | | | | | | |
| | NC-3000-H | 6 | 6 | 6 | 6 | 6 | 6 | 6 | 6 | 10.3 |
| | HP-850N | 4.4 | 4.4 | 4.4 | 4.4 | 4.4 | 4.4 | 4.4 | 4.4 | 4.1 |
| | MX-136 | 4 | 4 | 4 | 4 | 4 | 4 | 4 | — | — |
| | MX-965 | — | — | — | — | — | — | — | 4 | — |
| | KBM-573 | 0.3 | 0.3 | 0.3 | 0.3 | 0.3 | 0.3 | 0.3 | 0.3 | 0.3 |

| | | | | | | | | | |
|---|---|---|---|---|---|---|---|---|---|
| Flexibility | A | A | A | A | A | A | A | A | B |
| Relative magnetic | 4.9 | 5 | 4.7 | 4.6 | 5.2 | 5.1 | 5 | 4.9 | 4.9 |
| permeability | | | | | | | | | |
| Embeddability | A | A | A | B | B | B | A | A | A |

The numerical values shown for the composition in the table above indicate the amount of non-volatile content of each material.

### REFERENCE SIGNS LIST

1 . . . support, 2 . . . magnetic film, 3 . . . stack, 5 . . . magnetic layer, 10 . . . wiring substrate, 11 . . . substrate, 12 . . . wiring, 100 . . . circuit member.

1. A magnetic composition comprising: a magnetic powder; a thermosetting component; and a rubber component, wherein
a 10% cumulative particle size on a volume basis of the magnetic powder is 0.6 to 2.0 μm,
a 50% cumulative particle size on a volume basis of the magnetic powder is 1.1 to 3.6 μm, and
a 90% cumulative particle size on a volume basis of the magnetic powder is 2.1 to 6.3 μm.

2. The magnetic composition according to claim 1, wherein a content of the magnetic powder is 70% by mass or more, based on a total mass of non-volatile content in the magnetic composition.

3. The magnetic composition according to claim 1, further comprising particles comprising the rubber component.

4. The magnetic composition according to claim 1, wherein a content of the rubber component is 0.05 to 10.0% by mass, based on a total mass of non-volatile content in the magnetic composition.

5. The magnetic composition according to claim 1, wherein the thermosetting component comprises an epoxy group-containing compound and a phenolic curing agent.

6. A magnetic film comprising the magnetic composition according to claim 1.

7. A stack comprising: a support; and the magnetic film according to claim 6, provided on the support.

8. A circuit member comprising: a substrate having a wiring provided on a surface thereof; and a magnetic layer filling a gap between the wiring on the substrate, wherein
the magnetic layer comprises a cured product of the magnetic composition according to claim 1.

9. The circuit member according to claim 8, wherein the wiring is a coil wiring of an inductor.
